(19) United States
(12) Patent Application Publication
(10) Pub. No.: US 2026/0107534 A1
(43) Pub. Date: Apr. 16, 2026

(54) Low Resistivity Ohmic Contact to Group III-V Device

(71) Applicant: Newport Fab, LLC dba Tower Semiconductor Newport Beach, Newport Beach, CA (US)

(72) Inventors: Zhirong Tang, Lake Oswego, OR (US); Venkat Dukkipati, San Juan Capistrano, CA (US); Edward Preisler, San Clemente, CA (US); David J. Howard, Irvine, CA (US)

(21) Appl. No.: 18/913,319

(22) Filed: Oct. 11, 2024

(51) Int. Cl. H01L 29/45; H01L 21/285

(52) U.S. Cl. CPC H10D 62/85; H10D 64/0116; H10D 64/62

(57) ABSTRACT

A semiconductor structure includes a group III-V device, a dielectric layer over the group III-V device, and a contact hole in the dielectric layer over the group III-V device. A nickel-platinum (NiPt) liner is situated in the contact hole directly contacting the group III-V device. The NiPt liner may have a Ni composition from approximately forty percent to approximately ninety five percent (40% ≲ Ni ≲ 95%). The NiPt liner may directly contact P type gallium arsenide (GaAs). A contact resistivity between the NiPt liner and the group III-V device may be approximately one micro-Ohm-centimeter-squared (approximately 1 × 10⁻⁶ Ω•cm²).

### BACKGROUND

Group III-V compound semiconductors including at least one group III element, such as indium (In), gallium (Ga), aluminum (Al), and boron (B), and at least one group V element, such as arsenic (As), phosphorus (P), and nitrogen (N), have characteristics that make them advantageous for use in a variety devices, such as optical, optoelectronic, and radio frequency (RF) devices. However, engineering ohmic contacts to group III-V devices is generally significantly more complex compared to silicon (Si) or group IV devices. Contacts suitable for one group III-V device are not generally suitable for another group III-V device. Proper electrical performance of a group III-V device requires carefully consideration for how contacts interact with group III-V material.

A contact resistivity for a group III-V device can depend heavily on a variety of factors. The contact resistivity can drastically vary based on the material composition of the contact, as well as the material composition, dopant conductivity type, and dopant concentration of the group III-V material. Residues that naturally result during manufacturing, such as native oxide, can significantly impact resistivity. Contact materials conventionally chosen for low contact resistivity with group III-V devices, such as noble or near-noble metals, often create unforeseen complications in environments designed around popular complementary metal-oxide-semiconductor (CMOS) technology. Costly specialty manufacturing is often required for contacts lacking CMOS process compatibility. Conventional contacts also often have poor adhesion to common dielectrics, which can result in several disadvantages, including increasing contact resistivity. Further, conventional contacts to group III-V devices often have low thermal stability, degrading drastically after annealing above three hundred Celsius (300 °C). Their contact resistivities can become so high that they become unusable. Fabricating ohmic contacts without significant electrical performance tradeoffs becomes difficult and complex.

Thus, there is a need in the art for semiconductor structures with low resistivity ohmic contacts to group III-V devices.

### SUMMARY

The present disclosure is directed to low resistivity ohmic contact to group III-V devices, substantially as shown in and/or described in connection with at least one of the figures, and as set forth in the claims.

### BRIEF DESCRIPTION OF THE DRAWINGS

FIG. 1 illustrates a flowchart of an exemplary method for forming a semiconductor structure according to one implementation of the present application.

FIG. 2A illustrates a portion of a semiconductor structure processed in accordance with the flowchart of FIG. 1 according to one implementation of the present application.

FIG. 2B illustrates a portion of a semiconductor structure processed in accordance with the flowchart of FIG. 1 according to one implementation of the present application.

FIG. 2C illustrates a portion of a semiconductor structure processed in accordance with the flowchart of FIG. 1 according to one implementation of the present application.

FIG. 2D illustrates a portion of a semiconductor structure processed in accordance with the flowchart of FIG. 1 according to one implementation of the present application.

FIG. 2E illustrates a portion of a semiconductor structure processed in accordance with the flowchart of FIG. 1 according to one implementation of the present application.

FIG. 2F illustrates a portion of a semiconductor structure processed in accordance with the flowchart of FIG. 1 according to one implementation of the present application.

FIG. 2G illustrates a portion of a semiconductor structure processed in accordance with the flowchart of FIG. 1 according to one implementation of the present application.

FIG. 2H illustrates a portion of a semiconductor structure processed in accordance with the flowchart of FIG. 1 according to one implementation of the present application.

FIG. 3A illustrates a portion of a semiconductor structure processed in accordance with the flowchart of FIG. 1 according to one implementation of the present application.

FIG. 3B illustrates a portion of a semiconductor structure processed in accordance with the flowchart of FIG. 1 according to one implementation of the present application.

FIG. 3C illustrates a portion of a semiconductor structure processed in accordance with the flowchart of FIG. 1 according to one implementation of the present application.

FIG. 3D illustrates a portion of a semiconductor structure processed in accordance with the flowchart of FIG. 1 according to one implementation of the present application.

### DETAILED DESCRIPTION

The following description contains specific information pertaining to implementations in the present disclosure. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

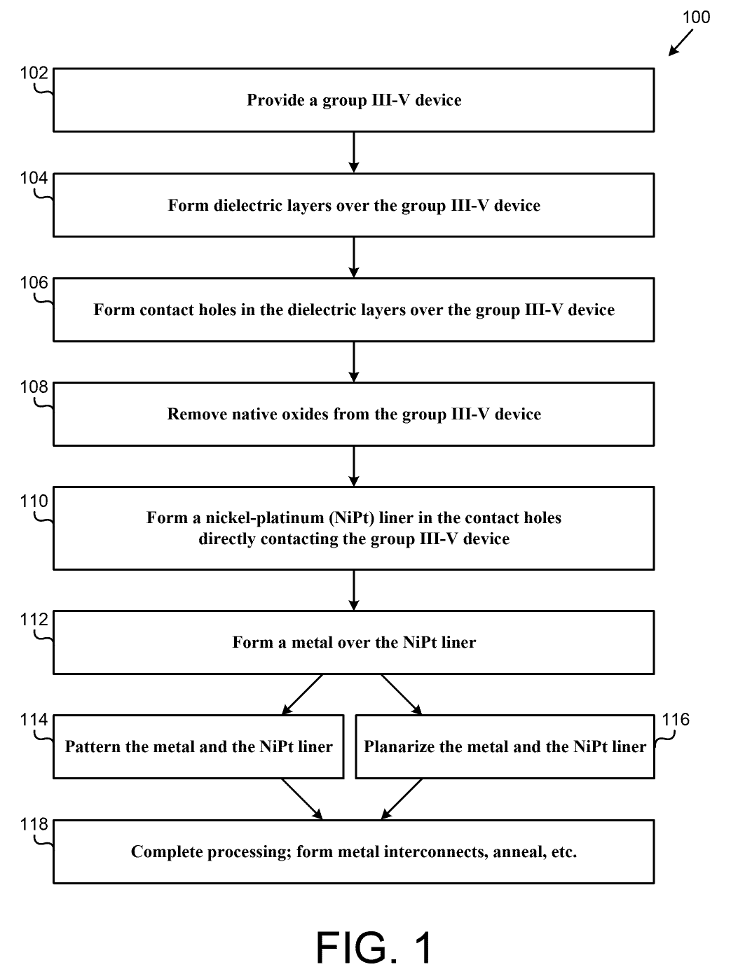

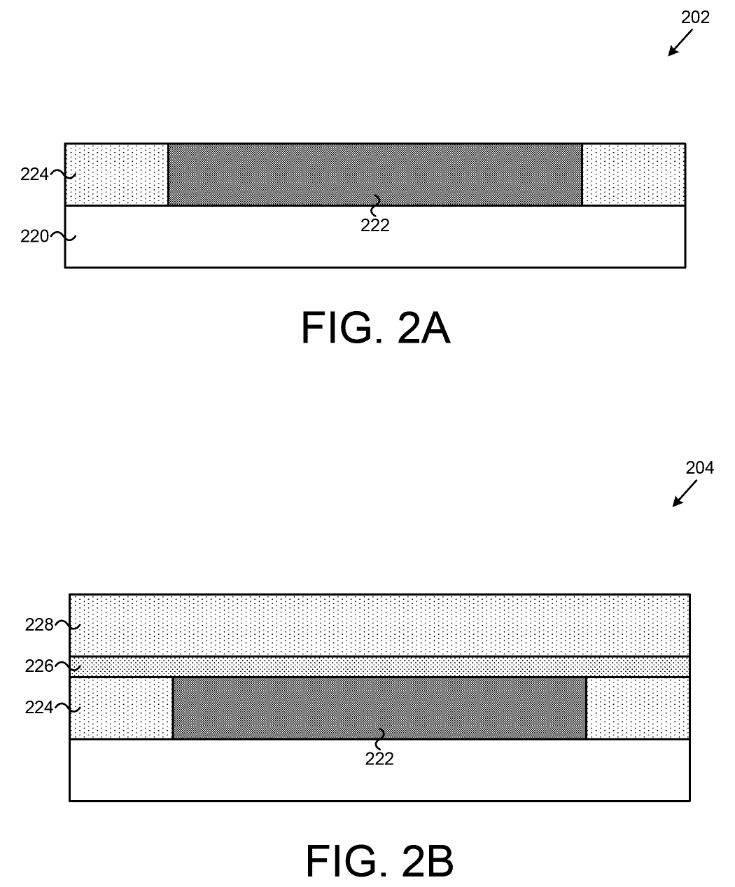

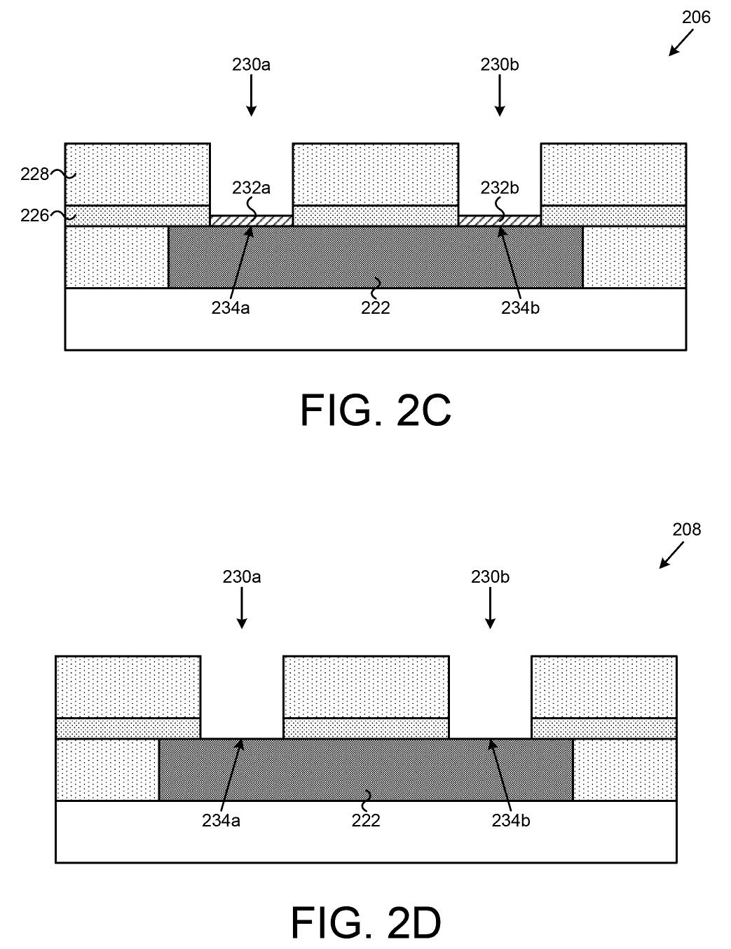

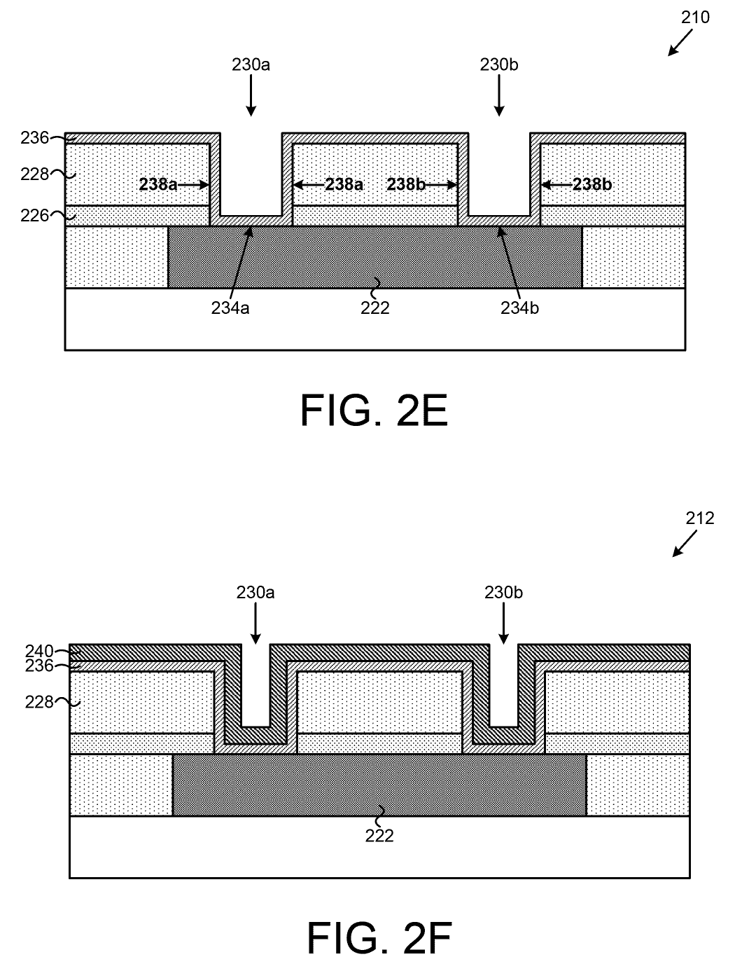

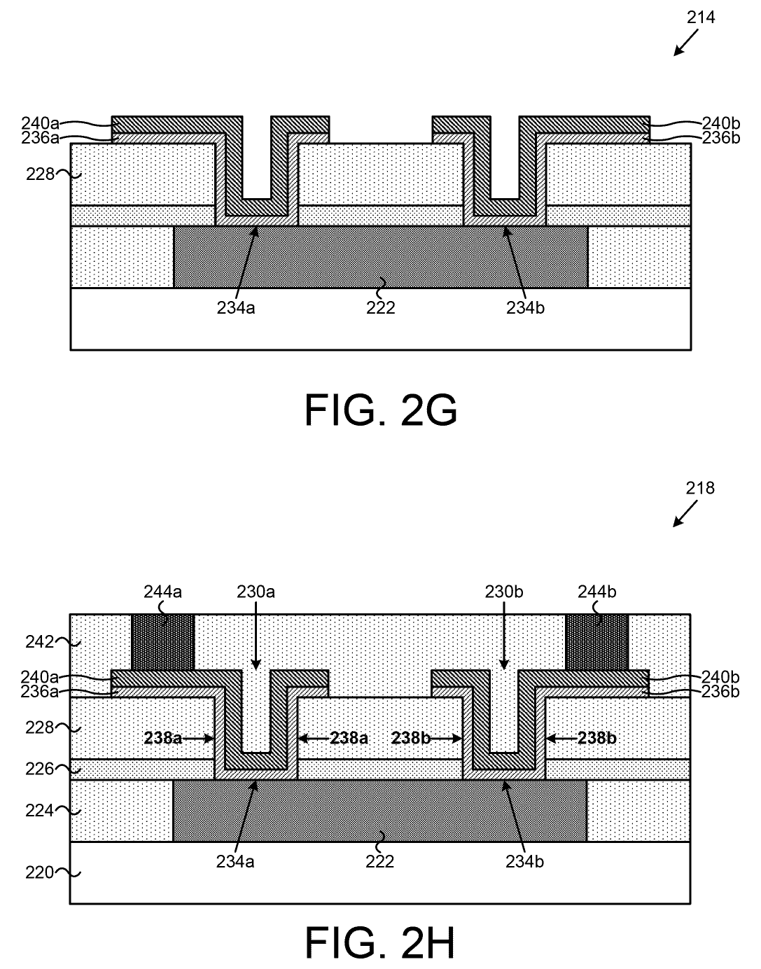

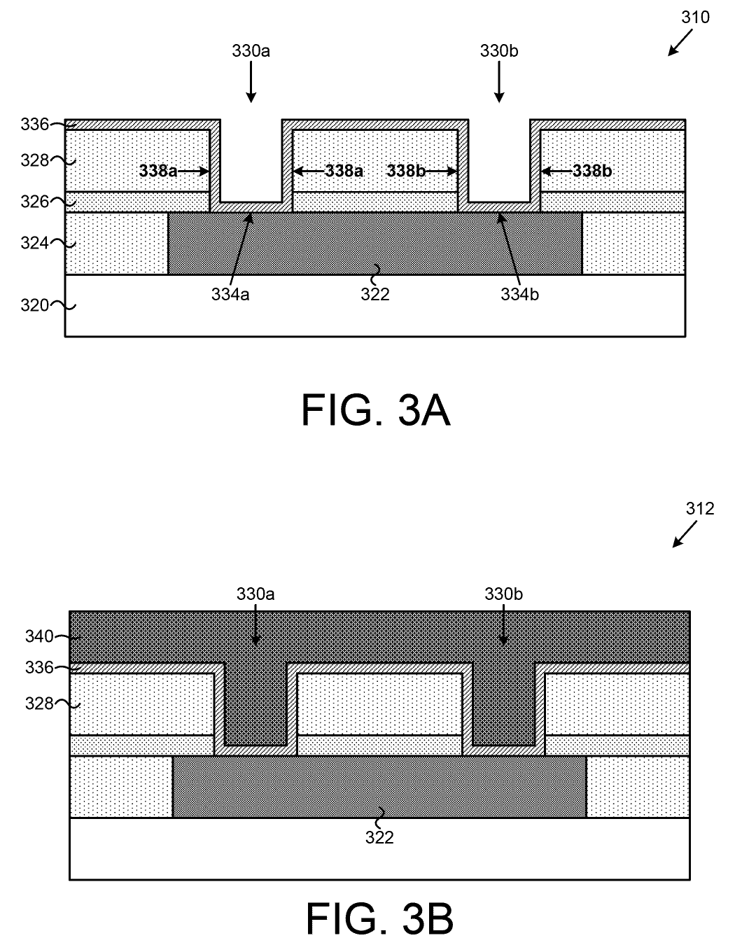

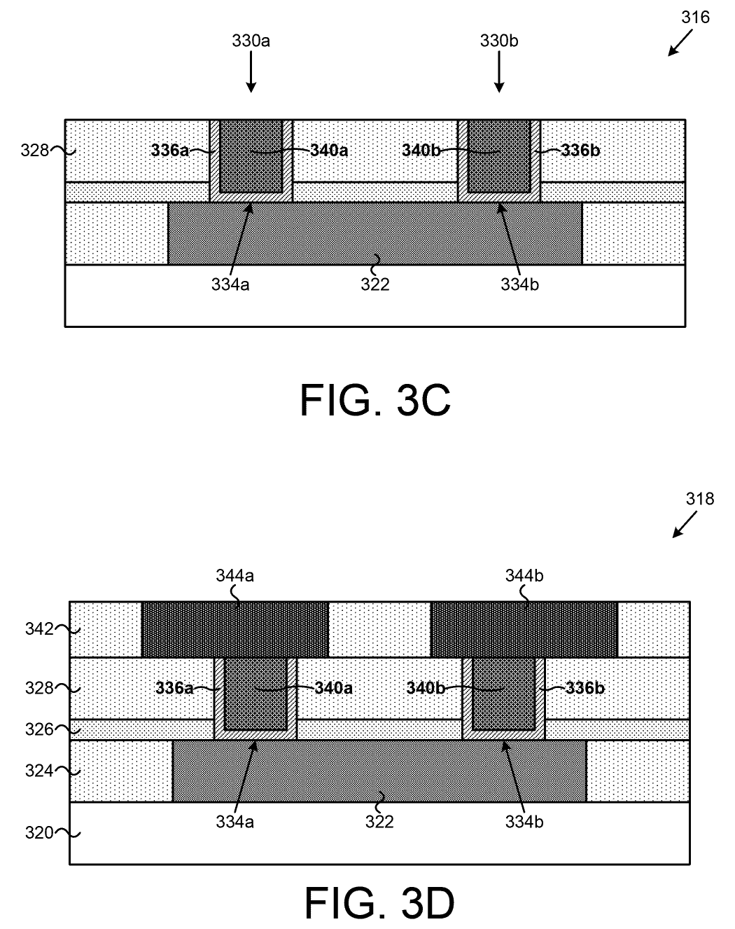

FIG. 1 illustrates a flowchart of an exemplary method for forming a semiconductor structure according to one implementation of the present application. Structures shown in FIGS. 2A through 3D illustrate the results of performing actions 102 through 118 shown in flowchart 100 of FIG. 1. For example, FIG. 2A shows a photonics structure after performing action 102 in FIG. 1, FIG. 2B shows a photonics structure after performing action 104 in FIG. 1, and so forth.

Actions 102 through 118 shown in flowchart 100 of FIG. 1 are sufficient to describe one implementation of the present inventive concepts. Other implementations of the present inventive concepts may utilize actions different from those shown in flowchart 100 of FIG. 1. Certain details and features have been left out of the flowchart that are apparent to a person of ordinary skill in the art. For example, an action may consist of one or more sub-actions or may involve specialized equipment or materials, as known in the art. Moreover, some actions, such as masking and cleaning actions, are omitted so as not to distract from the illustrated actions.

FIG. 2A illustrates a portion of a semiconductor structure processed in accordance with action 102 in flowchart 100 of FIG. 1 according to one implementation of the present application. As shown in FIG. 2A, in semiconductor structure 202, group III-V device 222 is provided.

Semiconductor structure 202 includes substrate 220, group III-V device 222, and dielectric layer 224. In one implementation, substrate 350 is an insulator, such as silicon oxide (SiO). In various implementations, substrate 350 is a silicon (Si), silicon-on-insulator (SOI), sapphire, complementary metal-oxide-semiconductor (CMOS), bipolar CMOS (BiCMOS), or group III-V substrate. Substrate 350 can have additional layers (not shown in FIG. 2A). In one implementation, substrate 350 can also comprise a plurality of active devices (not shown in FIG. 2A).

As shown in FIG. 2A, dielectric layer 224 is on substrate 220 and around group III-V device 222. Dielectric layer 224 can isolate group III-V device 222, for example, from additional devices in semiconductor structure 202 (not shown in FIG. 2A). In various implementations, dielectric layer 224 can comprise silicon oxide (SiO), silicon nitride (SiN), silicon oxynitride (SiON), a low-k dielectric, or another dielectric material.

Group III-V device 222 is situated on substrate 220, in dielectric layer 224. Group III-V device 222 can be any device comprising a group III-V semiconductor. As used herein, the phrase “group III-V” refers to a compound semiconductor including at least one group III element, such as indium (In), gallium (Ga), aluminum (Al), and boron (B), and at least one group V element, such as arsenic (As), phosphorus (P), and nitrogen (N). By way of example, a group III-V semiconductor may take the form of indium phosphide (InP). “Group III-V” can also refer to a compound semiconductor that includes an alloy of a group III element and/or an alloy of a group V element, such as indium gallium arsenide (In_{X}Ga_{1-X}As), indium gallium nitride (In_{X}Ga_{1-X}N), aluminum gallium nitride (Al_{X}Ga_{1-X}N), aluminum indium gallium nitride (Al_{X}In_{Y}Ga_{1-X-Y}N), gallium arsenide phosphide nitride (GaAs_{A}P_{B}N_{1-A-B}), and aluminum indium gallium arsenide phosphide nitride (Al_{X}In_{Y}Ga_{1-X-Y}As_{A}P_{B}N_{1-A-B}), for example. “Group III-V” also refers generally to any polarity including but not limited to Ga-polar, N-polar, semi-polar, or non-polar crystal orientations. A group III-V material may also include either the Wurtzitic, Zincblende, or mixed polytypes, and may include single-crystal, monocrystalline, polycrystalline, or amorphous structures.

In various implementations, group III-V device 222 can be a photodiode, phototransistor, laser, vertical cavity surface emitting laser (VCSEL), electro-absorption modulator (EAM), or any optoelectronic device configured to generate, receive, transmit, or modify light. Optoelectronic devices 226a, 226b, 226c, 226d, and 226e can be formed, for example, by depositing, patterning, doping, and/or performing other processing on group III-V semiconductor layers. In various implementations, group III-V device 222 can be a transistor, such as a high electron mobility transistor (HEMT), heterojunction bipolar transistor (HBT), or metal semiconductor field effect transistor (MESFET). In various implementations group III-V device 222 can be any radio frequency (RF) device or a sensor.

FIG. 2B illustrates a portion of a semiconductor structure processed in accordance with action 104 in flowchart 100 of FIG. 1 according to one implementation of the present application. As shown in FIG. 2B, in semiconductor structure 204, dielectric layers 226 and 228 are formed over group III-V device 222.

Dielectric layers 226 and 228 are also formed over dielectric layer 224. In various implementations, dielectric layers 226 and 228 can comprise SiO, SiN, SiON, a low-k dielectric, or another dielectric material. For example, dielectric layers 226 and 228 can be SiN and SiO respectively. In various implementations, more or fewer dielectric layers can be formed over dielectric layers 226 and 228.

FIG. 2C illustrates a portion of a semiconductor structure processed in accordance with action 106 in flowchart 100 of FIG. 1 according to one implementation of the present application. As shown in FIG. 2C, in semiconductor structure 206, contact holes 230a and 230b are formed in dielectric layers 226 and 228 over group III-V device 222.

Contact holes 230a and 230b can be formed by etching through dielectric layers 226 and 228 utilizing a plasma dry etch, for example, utilizing sulfur hexafluoride (SF₆) or methane (CH₄) with argon (Ar) and oxygen (O). In one implementation, forming contact holes 230a and 230b can involve selectively etching dielectric layer 228 while dielectric layer 226 performs as an etch stop layer, and then etching dielectric layer 226 to portions 234a and 234b of group III-V device 222. After forming contact holes 230a and 230b, semiconductor structure 206 may be cleaned and prepared for contact formation.

As shown in FIG. 2C, native oxides 232a and 232b are formed on portions 234a and 234b of group III-V device 222 that are exposed after forming contact holes 230a and 230b. Native oxides 232a and 232b can result from exposure of group III-V device 222 to water, oxygen, or other contaminants, such as during etching contact holes 230a and 230b, cleaning semiconductor structure 206, or transferring semiconductor structure 206 to another processing chamber. In various implementations, native oxides 232a and 232b can have a thickness of approximately one angstrom (1 Å) to approximately one hundred angstroms (100 Å).

FIG. 2D illustrates a portion of a semiconductor structure processed in accordance with action 108 in flowchart 100 of FIG. 1 according to one implementation of the present application. As shown in FIG. 2D, in semiconductor structure 208, native oxides 232a and 232b (shown in FIG. 2C) are removed from group III-V device 222.

Native oxides 232a and 232b are removed from portions 234a and 234b of group III-V device 222 at the bottom of contact holes 230a and 230b. Removing native oxides 232a and 232b exposes portions 234a and 234b of group III-V device 222. In FIG. 2D, portions 234a and 234b are areas of group III-V material. In one implementation, portions 234a and 234b are P type gallium arsenide (GaAs) portions of group III-V device 222. In other implementations, portions 234a and 234b can be another group III-V material and/or another conductivity type.

Native oxides 232a and 232b can be removed using any technique known in the art. For example, native oxides 232a and 232b can be removed using any technique described in United States Patent 9,653,291 to Yan et al. The disclosures and contents of the above-identified patent are hereby incorporated fully by reference into the present application. In one implementation, native oxides 232a and 232b can be removed using a plasma sputtering etch that is gentle and designed to only remove a thickness of approximately one hundred angstroms (100 Å) or less.

FIG. 2E illustrates a portion of a semiconductor structure processed in accordance with action 110 in flowchart 100 of FIG. 1 according to one implementation of the present application. As shown in FIG. 2E, in semiconductor structure 210, nickel-platinum (NiPt) liner 236 is formed in contact holes 230a and 230b directly contacting group III-V device 222.

In FIG. 2E, NiPt liner 236 is a conformal metal formed over portions of dielectric layer 228 and in contact holes 230a and 230b. NiPt liner 236 lines contact holes 230a and 230b without completely filling them. In contact holes 230a and 230b, NiPt liner 236 is along sidewalls 238a and 238b and along portions 234a and 234b. NiPt liner 236 successfully adheres to both group III-V material as well as dielectrics. NiPt liner 236 adheres along the heights of sidewalls 238a and 238b against both dielectric layers 226 and 228. NiPt liner 236 adheres along the widths of contact holes 230a and 230b against portions 234a and 234b of group III-V device 222. Thus, at the bottoms of contact holes 230a and 230b, NiPt liner 236 directly and ohmically contacts group III-V material of group III-V device 222. Advantageously, NiPt liner 236 provides a low resistivity ohmic contact to group III-V material. A contact resistivity between NiPt liner 236 and either of portions 234a and 234b of group III-V device 222 can be approximately one micro-Ohm-centimeter-squared (1 × 10⁻⁶ Ω•cm²) to approximately five micro-Ohm-centimeter-squared (5 × 10⁻⁶ Ω•cm²).

As used herein, the phrase “nickel-platinum (NiPt)” refers to a compound metal including at least nickel (Ni) and platinum (Pt), as opposed to, for example, a multi-layer including a Ni layer over/under a Pt layer. Preferably, NiPt liner 236 comprises a Ni composition from approximately forty percent to approximately ninety five percent (40% ≲ Ni ≲ 95%). As described below, such a composition for NiPt liner 236 can balance reduced contact resistivity, increased CMOS compatibility, increased adhesion, and increased thermal stability. In one example, NiPt liner 236 can have a Ni composition of approximately ninety five percent and have a Pt composition of approximately five percent (Ni_{0.95}Pt_{0.05}).

FIG. 2F illustrates a portion of a semiconductor structure processed in accordance with action 112 in flowchart 100 of FIG. 1 according to one implementation of the present application. As shown in FIG. 2F, in semiconductor structure 212, metal 240 is formed over NiPt liner 236.

In FIG. 2F, metal 240 is a thicker conformal metal formed over NiPt liner 236. Metal 240 is outside contact holes 230a and 230b above portions of dielectric layer 228, and in contact holes 230a and 230b above group III-V device 222. Metal 240 lines contact holes 230a and 230b without completely filling them. In one implementation, metal 240 can be an aluminum-copper (AlCu) alloy. In various implementations, metal 240 can be thicker or thinner than shown in FIG. 2F. Other layers may be situated between NiPt liner 236 and metal 240.

FIG. 2G illustrates a portion of a semiconductor structure processed in accordance with action 114 in flowchart 100 of FIG. 1 according to one implementation of the present application. As shown in FIG. 2G, in semiconductor structure 214, metal 240 and NiPt liner 236 (shown in FIG. 2F) are patterned.

The patterning removes selected areas on dielectric layer 228. Metal 240 is patterned into metals 240a and 240b. Likewise, NiPt liner 236 is patterned into NiPt liners 236a and 236b. Metal 240 and NiPt liner 236 can be patterned using any technique known in the art. As examples, metal 240 and NiPt liner 236 can be subtractively etched utilizing a plasma dry etch, or patterned utilizing a lift-off technique.

NiPt liner 236a and metal 240a together function as an electrical connector to portion 234a of group III-V device 222, and an electrical connector for subsequently formed metal interconnections. Likewise, NiPt liner 236b and metal 240b together function as an electrical connector to portion 234b of group III-V device 222, and an electrical connector for subsequently formed metal interconnections.

FIG. 2H illustrates a portion of a semiconductor structure processed in accordance with action 118 in flowchart 100 of FIG. 1 according to one implementation of the present application. As shown in FIG. 2H, in semiconductor structure 218, processing is completed.

In FIG. 2H, dielectric layer 242 is formed over metals 240a and 240b, as well as over dielectric layer 228. In various implementations, dielectric layer 242 can comprise SiO, SiN, SiON, a low-k dielectric, or another dielectric material. Metal interconnections 244a and 244b are formed in dielectric layer 242 on pad areas of metals 240a and 240b. Metal interconnections 244a and 244b electrically connect to portions 234a and 234b of group III-V device 222 through metals 240a and 240b and NiPt liners 236a and 236b. In various implementations, metal interconnections 244a and 244b can include Cu, Al, or an alloy thereof.

In one implementation, completing processing in accordance with action 118 in flowchart 100 of FIG. 1 includes performing a relatively high temperature anneal of semiconductor structure 218. The high temperature anneal can be performed at a temperature of approximately four hundred degrees Celsius (400 °C) or higher. Any additional processing actions known in the art can be performed, including a conventional back-end-of-line (BEOL) multi-level metallization (MLM) scheme.

Structures shown in FIGS. 3A through 3D illustrate the results of performing actions of the right branch in flowchart 100 of FIG. 1. FIG. 3A illustrates a portion of a semiconductor structure processed in accordance with action 110 in flowchart 100 of FIG. 1 according to one implementation of the present application. As shown in FIG. 3A, in semiconductor structure 310, NiPt liner 336 is formed in contact holes 330a and 330b directly contacting group III-V device 322.

Semiconductor structure 310 includes substrate 320, group III-V device 322 having group III-V portions 334a and 334b, dielectric layers 324, 326, and 328, contact holes 330a and 330b having sidewalls 338a and 338b, and NiPt liner 336. Substrate 320, group III-V device 322 having group III-V portions 334a and 334b, dielectric layers 324, 326, and 328, contact holes 330a and 330b having sidewalls 338a and 338b, and NiPt liner 336 in FIG. 3A generally correspond to like features in FIG. 2E. Except for differences noted below, semiconductor structure 310 in FIG. 3A is generally similar to semiconductor structure 210 in FIG. 2E, and may have any implementations and advantages described above.

FIG. 3B illustrates a portion of a semiconductor structure processed in accordance with action 112 in flowchart 100 of FIG. 1 according to one implementation of the present application. As shown in FIG. 3B, in semiconductor structure 312, metal 340 is formed over NiPt liner 336.

In FIG. 3B, metal 340 is a thicker metal formed over NiPt liner 336. Metal 340 is outside contact holes 330a and 330b above portions of dielectric layer 328, and in contact holes 330a and 330b above group III-V device 322. Metal 340 fills contact holes 330a and 330b. In one implementation, metal 340 can be Cu. In one implementation, metal 340 can be formed using a plate-up technique. In various implementations, metal 340 can be thicker or thinner than shown in FIG. 3B. Other layers may be situated between NiPt liner 336 and metal 340.

FIG. 3C illustrates a portion of a semiconductor structure processed in accordance with action 116 in flowchart 100 of FIG. 1 according to one implementation of the present application. As shown in FIG. 3C, in semiconductor structure 316, metal 340 and NiPt liner 336 (shown in FIG. 3B) are planarized.

Metal 340 and NiPt liner 336 can be planarized, for example, using chemical mechanical polishing (CMP). The planarizing removes selected areas above dielectric layer 328. Metal 340 is split into metals 340a and 340b. Likewise, NiPt liner 336 is split into NiPt liners 336a and 336b. The top surfaces of metals 340a and 340b and NiPt liners 336a and 336b are substantially coplanar with that of dielectric layer 328. As used herein, “substantially coplanar” refers to two surfaces being coplanar, except for normal dishing and other normal process variations associated with planarization.

NiPt liner 336a and metal 340a fill contact hole 330a, and together function as an electrical connector to portion 334a of group III-V device 322 and subsequently formed metal interconnections. Likewise, NiPt liner 336b and metal 340b fill contact hole 330b, and together function as an electrical connector to portion 334b of group III-V device 322 and subsequently formed metal interconnections.

FIG. 3D illustrates a portion of a semiconductor structure processed in accordance with action 118 in flowchart 100 of FIG. 1 according to one implementation of the present application. As shown in FIG. 3D, in semiconductor structure 318, processing is completed.

In FIG. 3D, dielectric layer 342 is formed over metals 340a and 340b and NiPt liners 336a and 336b, as well as over dielectric layer 328. In various implementations, dielectric layer 342 can comprise SiO, SiN, SiON, a low-k dielectric, or another dielectric material. Metal interconnections 344a and 344b are formed in dielectric layer 342 covering metals 340a and 340b and NiPt liners 336a and 336b. Metal interconnections 344a and 344b electrically connect to portions 334a and 334b of group III-V device 322 through metals 340a and 340b and NiPt liners 336a and 336b. In one implementation, metal interconnections 344a and 344b can include Cu. In one implementation, metal interconnections 344a and 344b are formed using a damascene technique. As described above, completing processing can also include performing a relatively high temperature anneal of semiconductor structure 318, and forming a BEOL MLM.

Semiconductor structures, such as semiconductor structure 218 in FIG. 2H and semiconductor structure 318 in FIG. 3D, formed according to the present invention are able to provide several advantages. First, since NiPt liners 236a and 236b in contact holes 230a and 230b directly contact group III-V material portions 234a and 234b, semiconductor structure 218 provides low resistivity ohmic contact to group III-V device 222. Since native oxides 232a and 232b (shown in FIG. 2C) were removed from group III-V device 222, NiPt liners 236a and 236b contact group III-V material portions 234a and 234b cleanly and uniformly, further lowering contact resistivity. A contact resistivity can be approximately one micro-Ohm-centimeter-squared (1 × 10⁻⁶ Ω•cm²) to approximately five micro-Ohm-centimeter-squared (5 × 10⁻⁶ Ω•cm²). It has been found that NiPt liners 236a and 236b provide particularly low contact resistivity (closer to 1 × 10⁻⁶ Ω•cm²) where portions 234a and 234b are P type GaAs. It has also been found that NiPt liners 236a and 236b provide particularly low contact resistivity when a composition ratio of Ni to Pt is approximately forty to sixty (40:60) to approximately ninety five to five (95:5). Composition ratios significantly outside this range tend to decrease performance.

Second, NiPt liners 236a and 236b according to present invention improve CMOS process compatibility. Conventional low resistivity contacts to group III-V devices often create unforeseen complications for typical CMOS processes, and require specialty manufacturing. In contrast, NiPt liners 236a and 236b allow for low resistivity contacts to group III-V device 222 and can be manufactured without significant complications to typical CMOS processes, especially when the Ni composition is greater than or approximately equal to forty percent (40% ≲ Ni).

Third, NiPt liners 236a and 236b successfully adhere to both group III-V material as well as dielectric layers 226 and 228. Conventional contacts to group III-V devices often have poor adhesion to common dielectrics. For example, if NiPt liners 236a and 236b in FIG. 2H were replaced with conventional materials, they may peel from sidewalls 238a and 238b of contact holes 230a and 230b, which can result in several disadvantages, including increasing contact resistivity. In contrast, NiPt liners 236a and 236b adhere to sidewalls 238a and 238b against both dielectric layers 226 and 228. As another example, if NiPt liners 336a and 336b in FIG. 3D were replaced with conventional materials, they may peel from dielectric layers 326 and 328. Thus, when forming metal interconnections 344a and 344b, metal may undesirably be deposited in gaps between NiPt liners 336a and 336b and dielectric layers 326 and 328, resulting in current crowding and other negative side effects.

Fourth, NiPt liners 236a and 236b according to present invention improve temperature stability. Conventional contacts to group III-V devices degrade drastically after annealing above three hundred Celsius (300 °C). Their contact resistivities can become so high that they become unusable. In contrast, NiPt liners 236a and 236b can withstand a high temperature anneal at approximately four hundred degrees Celsius (400 °C) or higher without a significant change in contact resistivity.

Thus, various implementations of the present application achieve reduced contact resistivity utilizing the semiconductor structures and methods of the present application and novel combinations to overcome the deficiencies in the art. From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described above, but many rearrangements, modifications, and substitutions are possible without departing from the scope of the present disclosure.

1. A method comprising:
providing a group III-V device;
forming at least one dielectric layer over said group III-V device;
forming a contact hole in said at least one dielectric layer over said group III-V device;
forming a nickel-platinum (NiPt) liner in said contact hole directly contacting said group III-V device.

2. The method of claim 1, wherein said NiPt liner comprises a Ni composition from approximately forty percent to approximately ninety five percent (40% ≲ Ni ≲ 95%).

3. The method of claim 1, wherein said NiPt liner directly contacts gallium arsenide (GaAs).

4. The method of claim 1, wherein said NiPt liner directly contacts P type group III-V material.

5. The method of claim 1, wherein said NiPt liner directly contacts P type GaAs.

6. The method of claim 1, wherein a contact resistivity between said NiPt liner and said group III-V device is approximately one micro-Ohm-centimeter-squared to approximately five micro-Ohm-centimeter-squared (approximately 1 × 10⁻⁶ Ω•cm² to approximately 5 × 10⁻⁶ Ω•cm²).

7. The method of claim 1, wherein said NiPt liner adheres to a sidewall of said contact hole.

8. The method of claim 1, further comprising removing a native oxide from said group III-V device before said forming said NiPt liner.

9. The method of claim 1, further comprising performing a high temperature anneal after said forming said NiPt liner.

10. The method of claim 1, further comprising forming a metal over said NiPt liner, and patterning said metal and said NiPt liner.

11. The method of claim 1, further comprising forming a metal over said NiPt liner, and planarizing said metal and said NiPt liner.

12. A semiconductor structure comprising:
a group III-V device;
at least one dielectric layer over said group III-V device;
a contact hole in said at least one dielectric layer over said group III-V device;
a nickel-platinum (NiPt) liner in said contact hole directly contacting said group III-V device.

13. The semiconductor structure of claim 12, wherein said NiPt liner comprises a Ni composition from approximately forty percent to approximately ninety five percent (40% ≲ Ni ≲ 95%).

14. The semiconductor structure of claim 12, wherein said NiPt liner directly contacts gallium arsenide (GaAs).

15. The semiconductor structure of claim 12, wherein said NiPt liner directly contacts P type group III-V material.

16. The semiconductor structure of claim 12, wherein said NiPt liner directly contacts P type GaAs.

17. The semiconductor structure of claim 12, wherein a contact resistivity between said NiPt liner and said group III-V device is approximately one micro-Ohm-centimeter-squared to approximately five micro-Ohm-centimeter-squared (approximately 1 × 10⁻⁶ Ω•cm² to approximately 5 × 10⁻⁶ Ω•cm²).

18. The semiconductor structure of claim 12, wherein said NiPt liner adheres to a sidewall of said contact hole.

19. The semiconductor structure of claim 12, further comprising a metal over said NiPt liner, said metal in said contact hole and outside said contact hole over said at least one dielectric.

20. The semiconductor structure of claim 12, further comprising a metal over said NiPt liner, said metal and said NiPt liner substantially coplanar with said at least one dielectric layer.
